(19) United States
(12) Patent Application Publication
(10) Pub. No.: US 2019/0212397 A1
(43) Pub. Date: Jul. 11, 2019

(54) DETERIORATION DETERMINATION DEVICE FOR SECONDARY BATTERY

(71) Applicant: NTN CORPORATION, Osaka (JP)

(72) Inventor: Hiroyuki YAMADA, Iwata (JP)

(73) Assignee: NTN CORPORATION, Osaka (JP)

(21) Appl. No.: 16/354,865

(22) Filed: Mar. 15, 2019

Related U.S. Application Data
(63) Continuation of application No. PCT/JP2017/033918, filed on Sep. 20, 2017.

(30) Foreign Application Priority Data
Sep. 21, 2016 (JP) 2016-184024

(51) Int. Cl. G01R 31/392; G01R 31/389; G01R 31/3842; G01R 31/396; H01M 10/48; H01M 10/42

(52) U.S. Cl. CPC G01R 31/392; G01R 31/389; G01R 31/3842; H01M 2010/4278; H01M 10/482; H01M 10/425; G01R 31/396

(57) ABSTRACT

In a power supply in which a plurality of battery groups that are series-connection assemblies of batteries are connected in parallel, degradation is determined for each battery. The degradation determination device includes: a plurality of voltage sensor units each of which individually detects inter-terminal voltages of the plurality of batteries in the corresponding battery group, individually calculates AC components from detected signals thereof, and transmits calculation results as measurement values by one wireless unit; a measurement current application device which applies a measurement current including an AC component to the battery groups; and a controller which receives the measurement values transmitted from each voltage sensor unit, calculates an internal resistance of each battery by using the received measurement value, and determines degradation of the battery on the basis of the internal resistance.

### CROSS REFERENCE TO THE RELATED APPLICATION

This application is a continuation application, under 35 U.S.C. §111(a), of international application No. PCT/JP2017/033918, filed Sep. 20, 2017, which is based on and claims Convention priority to Japanese patent application No. 2016-184024, filed Sep. 21, 2016, the entire disclosure of which is herein incorporated by reference as a part of this application.

### BACKGROUND OF THE INVENTION

### Field of the Invention

The present invention relates to a secondary battery deterioration or degradation determination device that determines deterioration or degradation of secondary batteries used in an emergency power supply or the like in a data center, a mobile phone base station, or other various types of power supply devices for which stable supply of power is required.

### Description of Related Art

Stable supply of power is important to data centers, mobile phone base stations, etc. A commercial AC power supply is used in a normal state, and an emergency power supply in which secondary batteries are used is provided as an uninterruptible power supply for a case where the commercial AC power supply is stopped. Modes for charging the emergency power supply include: a trickle charge mode in which charging is performed with a minute current in a normal state using a charging circuit; and a float charge mode in which a load and a secondary battery are connected in parallel with respect to a rectifier, and charging is performed while the load is being operated by applying a constant current. Generally, the trickle charge mode is adopted for many emergency power supplies. For the emergency power supply, a voltage and a current that allow a load, which is driven by a commercial power supply, to be driven are required, and one secondary battery has a low voltage and also has a small capacity. Thus, the emergency power supply is configured by connecting, in parallel, a plurality of battery groups each including a plurality of batteries connected in series. Each of the batteries is a lead storage battery or a lithium ion battery.

In such an emergency power supply, the voltage of each battery is decreased due to degradation of the battery. Thus, for ensuring reliability, desirably, battery degradation determination is performed and a battery that has been degraded is replaced. However, a device capable of accurately determining degradation of multiple batteries in a large-scale emergency power supply in a data center, a mobile phone base station, or the like has not been proposed yet.

Examples of proposals of conventional battery degradation determination include a proposal in which a vehicle-mounted-battery checker collectively measures the entire battery (e.g., Patent Document 1), a proposal in which a pulse-shaped voltage is applied to a battery, and the internal impedance of the entire battery is calculated from an input voltage and the response voltage (e.g., Patent Document 2), and a proposal of a method in which the internal resistances of individual cells connected in series in a battery are measured and degradation determination is performed (e.g., Patent Document 3), etc. In addition, a battery tester employing an AC four-terminal method has been commercialized as a handy checker for measuring a very small resistance value such as an internal resistance of a battery (e.g., Non-Patent Document 1).

In Patent Documents 1 and 2, wireless transmission of data has also been proposed, and reduction of handling a cable or manual work and data management by a computer have also been proposed.

### RELATED DOCUMENT

### [Patent Document]

[Patent Document 1] JP Laid-open Patent Publication No. H10-170615

[Patent Document 2] JP Laid-open Patent Publication No. 2005-100969

[Patent Document 3] JP Laid-open Patent Publication No. 2010-164441

### [Non-Patent Document]

[Non-Patent Document 1] AC 4-terminal-method battery tester, internal resistance measuring instrument IW7807-BP (Rev. 1. 7. 1, Feb. 16, 2015, Tokyo Devices)

(https://tokyodevices.jp/system/attachments/files/000/000/298/original/IW7807-BP-F_MANUAL.pdf) With the conventional handy checker (Non-Patent Document 1), the number of measurement locations is excessive in an emergency power supply in which dozens or hundreds of batteries are connected. Thus, use of the conventional handy checker is not feasible. In each of the technologies of Patent Documents 1 and 2, the entirety of a power supply including batteries is measured, and the individual batteries, that is, individual cells, are not measured.

Thus, the accuracy of degradation determination is low, and individual batteries that have been degraded cannot be identified.

By measuring the internal resistance of each cell connected in series, the technology of Patent Document 3 leads to a technology to improve the accuracy of degradation determination and identify individual batteries that have been degraded. However, the reference potential (ground level) of each voltage sensor is negative terminal potential of each cell. Thus, in this state, in a battery group in which dozens to hundreds of batteries are directly connected to each other, the reference potentials of the respective batteries are all different from each other. How to deal with the differences in reference potential is not disclosed in this document. Generally, in order to acquire the potential of each cell, it is necessary to detect a potential difference through differential operation or to use an isolation transformer, so that the configuration becomes complicated and expensive.

As a device that solves these problems, a secondary battery degradation determination device shown in FIG. 11 has been previously proposed (Japanese Laid-open Patent Publication No. 2017-150925). Specifically, this device is a secondary battery degradation determination device that determines degradation of each battery 2 in a power supply 1 in which a plurality of battery groups 3 each including a plurality of batteries 2 that are secondary batteries and are connected in series are connected in parallel. The secondary battery degradation determination device includes: a plurality of voltage sensor units 7 individually connected to the respective batteries 2; a measurement current application device 9 that applies a measurement current including an AC component to each battery group 3; a sensor wireless communicator 10A that is provided to each voltage sensor unit 7 and wirelessly transmits a measurement value of the voltage of the AC component measured; and a controller 11 that receives the measurement value transmitted by each sensor wireless communicator 10A, calculates the internal resistance of each battery 2 by using the received measurement value, and determines degradation of the battery 2 on the basis of the internal resistance. In FIG. 11, portions or sections corresponding to those in a later-described embodiment are designated by the same reference numerals.

According to this configuration, the measurement value of each voltage sensor unit 7 is wirelessly transmitted to the controller 11. Since wireless transmission is performed as described above, even when the multiple batteries 2 connected in series and forming the battery groups 3 are present, for example, even when the number of such batteries is dozens to hundreds, the reference potential (ground level) of a detection unit 7a of each voltage sensor unit 7 can be common, and there is no need to care about the reference potential. Thus, differential operation and an isolation transformer are not necessary. In addition, since the measurement value of each of the plurality of voltage sensors is wirelessly transmitted, complicated wiring is not necessary. Accordingly, the configuration can be simple and inexpensive. In addition, degradation of the entire power supply 1 to be subjected to degradation determination is not determined but degradation of each battery 2 is determined. Thus, degradation of each battery 2 can be accurately determined.

However, since the sensor wireless communicator 10A is provided for each voltage sensor (detection unit 7a) equipped for each individual battery 2, the number of the sensor wireless communicator 10A is large and the configuration is complicated and expensive. Since the sensor wireless communicator 10A are expensive components for performing wireless communication, providing a large number of such sensor wireless communicator 10A makes the entire degradation determination device expensive.

### SUMMARY OF THE INVENTION

An object of the present invention is to provide a secondary battery degradation determination device that can be produced more simply at lower cost and that can accurately determine degradation of each battery in a power supply in which a plurality of battery groups each including a plurality of batteries that are secondary batteries and are connected in series are connected in parallel.

Hereinafter, in order to facilitate understanding of the present invention, the present invention will be described with reference to the reference numerals in embodiments for the sake of convenience.

A secondary battery degradation determination device of the present invention is a secondary battery degradation determination device that determines degradation of a battery in a power supply 1 in which a plurality of battery groups 3 each including a plurality of batteries 2 that are secondary batteries and are connected in series are connected in parallel, the secondary battery degradation determination device including: a plurality of voltage sensor units 7 each configured to individually detect inter-terminal voltages of the plurality of batteries 2 in the corresponding battery group 3, individually calculate AC components from detected signals thereof, and transmit calculation results as measurement values by one wireless unit 10; a current sensor 8 configured to detect a current of each battery group 3; a measurement current application device 9 configured to apply a measurement current including an AC component to the battery groups 3; and a controller 11 configured to receive the measurement values transmitted from each voltage sensor unit 7, calculate an internal resistance of each battery 2 by using the received measurement values, and determine degradation of each battery 2 on the basis of the internal resistance.

The AC component as used herein is a component of which the magnitude of a voltage or current repeatedly changes, but may have a voltage or current of which the direction is constantly fixed, and may be, for example, a ripple current or a pulse current. The “battery” may be a battery including a plurality of cells connected in series, or may be a single cell. In addition, the “controller” is not limited to a single component, but may be divided into, for example, a main controller 11A including a receiver for receiving the measurement value, and an information processing device such as a data server 13 connected to the main controller 11A via a communication part 12 such as a LAN and configured to calculate the internal resistance of each battery 2.

According to this configuration, each voltage sensor unit 7 wirelessly transmits the voltages of the individual batteries 2 to the controller 11. Even when the multiple batteries 2 connected in series and forming the battery groups 3 are present, for example, even when the number of such batteries is dozens to hundreds, since wireless transmission is performed, the reference potential (ground level) of each detection unit 7a which is a voltage sensor or the like can be common, and there is no need to care about the reference potential. Thus, differential operation and an isolation transformer for considering reference potential are not necessary.

In addition, since the measurement values of the multiple batteries 2 are transmitted wirelessly, complicated wiring is not needed, so that the configuration is simplified and thus production can be performed at low cost. In this case, since the individual measurement values of the plurality of batteries 2 are transmitted by one wireless unit 10, the number of wireless units 10 can be decreased, so that the entire configuration of the degradation determination device is simplified and thus the degradation determination device can be produced at low cost.

Degradation of the entire power supply 1 to be subjected to degradation determination is not determined, but degradation of each battery 2 is determined. In addition, for the determination, the measurement current including the AC component is applied, the internal resistance of each battery 2 is calculated by using the transmitted measurement value of the voltage and the measurement value of the current sensor 8, and degradation of the battery 2 is determined on the basis of the internal resistance. Thus, degradation determination can be accurately performed. The internal resistance of the battery 2 is closely related to the capacity of the battery 2, that is, the degree of degradation of the battery 2, and thus degradation of the battery 2 can be accurately determined when the internal resistance is known.

In the present invention, each voltage sensor unit 7 may include: a plurality of detection units 7a configured to individually detect the inter-terminal voltages; and a plurality of calculation units 7b configured to individually calculate the AC components from signals detected by the respective detection units. In the case of this configuration, since the detection unit 7a and the calculation unit 7b are provided for each battery 2, the configuration is clear.

In the present invention, each voltage sensor unit 7 may include: one detection unit 7a configured to individually detect the inter-terminal voltages; a switch unit 7c configured to perform switching among the plurality of batteries 2 to be connected to the detection unit 7a; and one calculation unit 7b configured to individually calculate the AC component from each signal detected by the detection unit 7a. In the case of this configuration, although the switch unit 7c is needed, the required number of the detection units 7a and the required number of the calculation units 7b are both only one. Therefore, the number of circuit elements for the detection unit 7a, the calculation unit 7b, or the switch unit 7c is decreased.

In the present invention, each voltage sensor unit 7 may include: a plurality of detection units 7a configured to individually detect the inter-terminal voltages; a data selecting unit 7d configured to switchably select a signal detected by each detection unit 7a and output the selected signal; and one calculation unit 7b configured to individually calculate the AC component from the signal selected by the data selecting unit 7d. In the case of this configuration, although the data selecting unit 7d is needed, the required number of the calculation units 7b is only one. Therefore, the number of circuit elements for the detection unit 7a, the calculation unit 7b, or the data selecting unit 7d is decreased.

In the present invention, an entirety of each voltage sensor unit 7 may be an integrated component in which all constituent elements thereof are assembled in one housing 7g. As a configuration in which all the components are assembled in one housing 7g, elements as these constituent elements may be mounted on the common circuit board, or may be formed as one integrated circuit chip. Such an integrated component is excellent in handling property and storage property.

In the case of the configuration in which the switch unit 7c is provided, the switch unit 7c may use in common a terminal Tau having the lowest potential among the plurality of batteries 2 connected in series that are subjected to detection by the corresponding one voltage sensor unit 7 (FIG. 4 shows an example thereof). In the case of this configuration, the configuration of the switch unit 7c is simplified.

In the case of the configuration in which the switch unit 7c is provided, the switch unit 7c may sequentially switch, for each battery 2, both terminals 7au, 7ah on a low potential side and a high potential side that are to be connected to the detection unit 7a. In the case of this configuration, only the switch unit 7c is connected to the input side of the detection unit 7a, and therefore the wiring is simplified.

Any combination of at least two constructions, disclosed in the appended claims and/or the specification and/or the accompanying drawings should be construed as included within the scope of the present invention. In particular, any combination of two or more of the appended claims should be equally construed as included within the scope of the present invention.

### BRIEF DESCRIPTION OF THE DRAWINGS

In any event, the present invention will become more clearly understood from the following description of preferred embodiments thereof, when taken in conjunction with the accompanying drawings. However, the embodiments and the drawings are given only for the purpose of illustration and explanation, and are not to be taken as limiting the scope of the present invention in any way whatsoever, which scope is to be determined by the appended claims. In the accompanying drawings, like reference numerals are used to denote like parts throughout the several views, and:

FIG. 1 is a circuit diagram of a secondary battery degradation determination device according to a first embodiment of the present invention;

FIG. 2 is a block diagram showing an example of a conceptual configuration of a voltage sensor unit in the degradation determination device;

FIG. 3 is a block diagram showing another example of a conceptual configuration of a voltage sensor unit in the degradation determination device;

FIG. 4 is a block diagram showing still another example of a conceptual configuration of a voltage sensor unit in the degradation determination device;

FIG. 5 is a block diagram showing still another example of a conceptual configuration of a voltage sensor unit in the degradation determination device;

FIG. 6 is a block diagram showing still another example of a conceptual configuration of a voltage sensor unit in the degradation determination device;

FIG. 7 is a block diagram showing a conceptual configuration of voltage sensor units and a controller in the secondary battery degradation determination device;

FIG. 8 is a flowchart showing an example of operation of the secondary battery degradation determination device;

FIG. 9 is a circuit diagram of a secondary battery degradation determination device according to a second embodiment of the present invention;

FIG. 10 is a circuit diagram of a secondary battery degradation determination device according to a third embodiment of the present invention; and

FIG. 11 is a circuit diagram of a secondary battery degradation determination device according to a reference proposal example.

### DESCRIPTION OF EMBODIMENTS

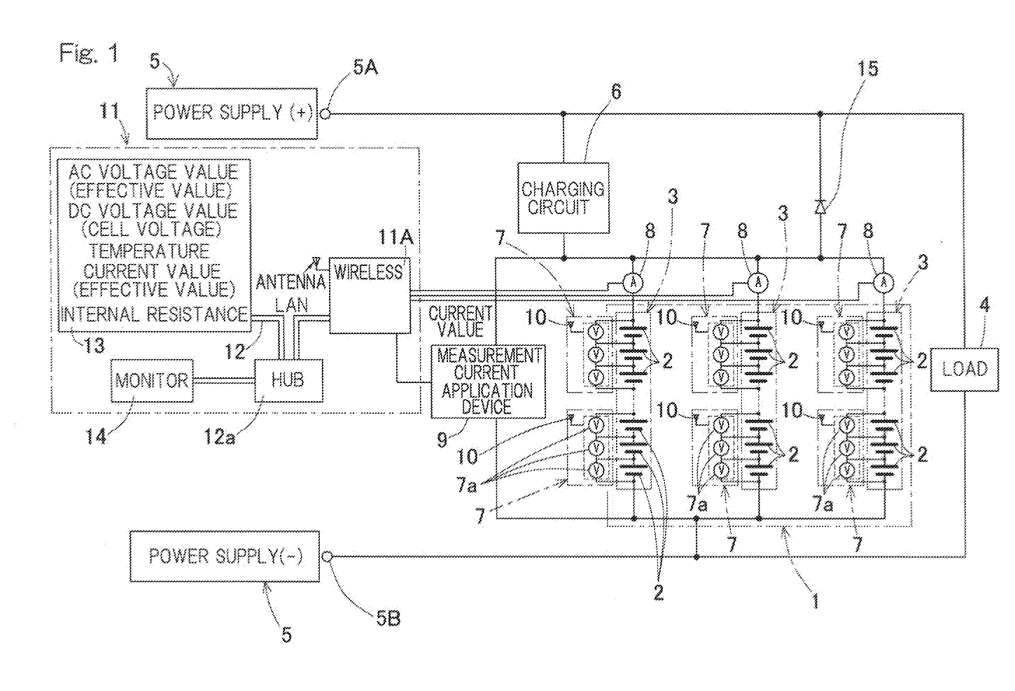

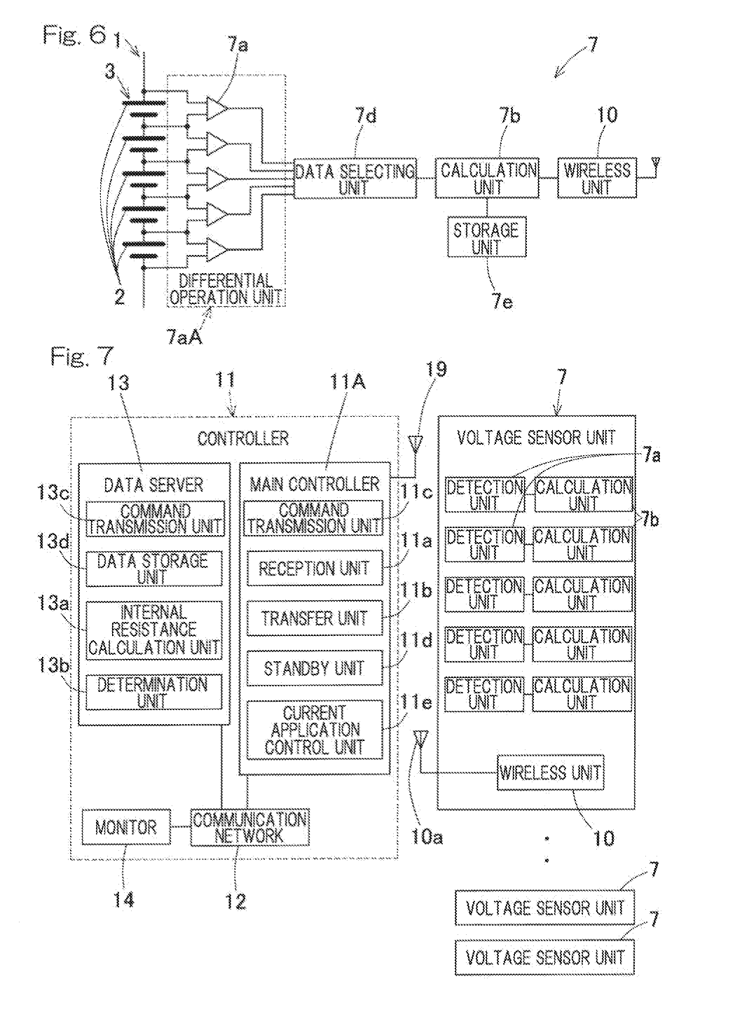

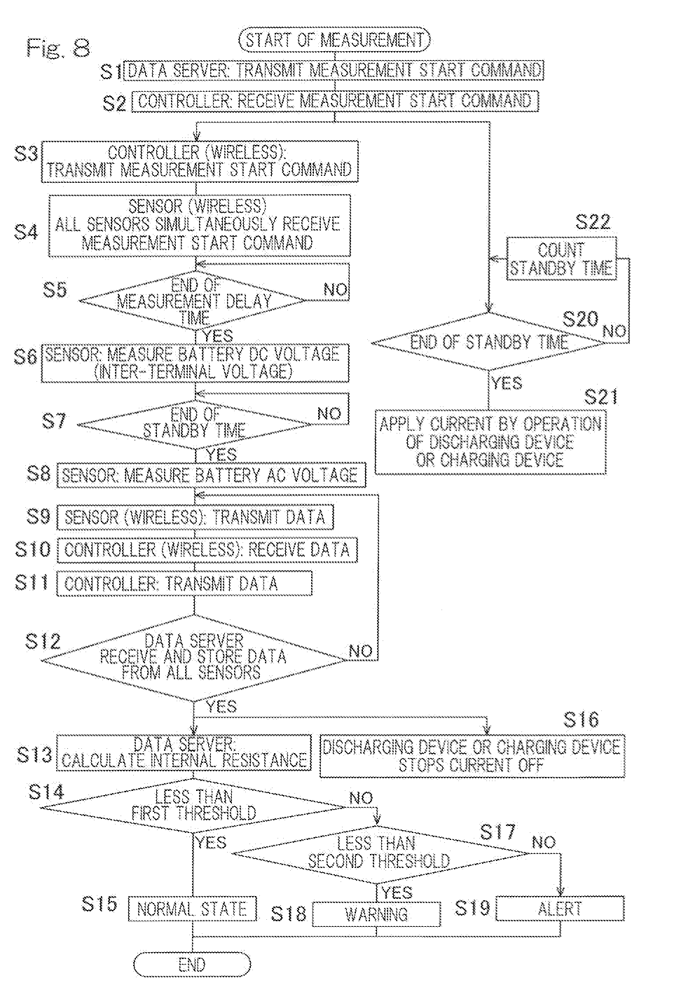

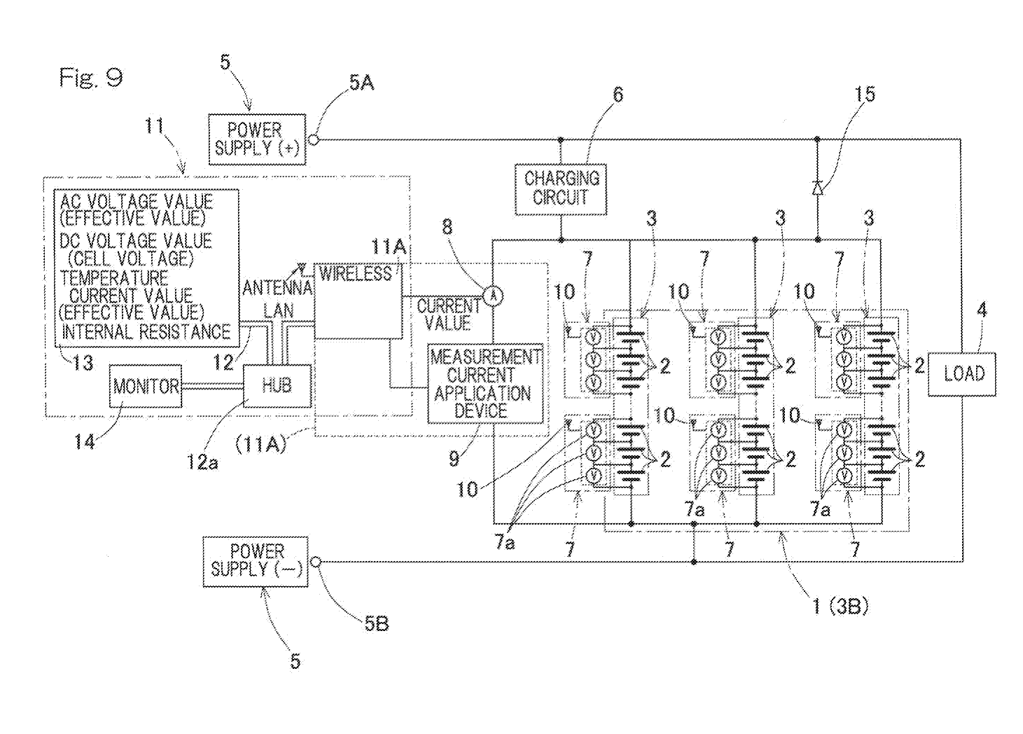

A secondary battery degradation determination device according to a first embodiment of the present invention will be described with reference to FIG. 1 to FIG. 3, FIG. 7, and FIG. 8. In FIG. 1, a power supply 1 to be subjected to degradation determination is an emergency power supply in a data center, a mobile phone base station, or other various types of power supply devices for which stable supply of power is required. The power supply 1 has a plurality of battery groups 3 each including a plurality of batteries 2 that are secondary batteries and are connected in series. These battery groups 3 are connected in parallel to form a later-described parallel-connection assembly 3B and are connected to a load 4. Each battery 2 may be a single cell or may be a battery including a plurality of cells connected in series.

A main power supply 5 has positive and negative terminals 5A and 5B that are respectively connected to positive and negative terminals of the load 4. The emergency power supply 1 is connected via a charging circuit 6 and a diode 15 to a positive terminal 5A, and is connected directly to the negative terminal 5B. The diode 15 is connected in parallel with the charging circuit 6 so as to be directed such that a current is caused to flow from the emergency power supply 1 to the load 4. The main power supply 5 includes, for example, a DC power supply that is connected to a commercial AC power supply via a rectifier circuit and a smoothing circuit (both of which are not shown) and performs conversion to DC power.

The positive potential of the emergency power supply 1 is lower than the positive potential of the main power supply 5 and current does not normally flow to the load 4. However, when the main power supply 5 is stopped or the function of the main power supply 5 is diminished, the potential at the main power supply 5 side is decreased, and thus power is supplied to the load 4 via the diode 15 by electric charge stored in the emergency power supply 1. A charge mode in which the charging circuit 6 is connected as described above is referred to as trickle charge mode.

The secondary battery degradation determination device of the present embodiment determines degradation of each battery 2 in such a power supply 1. The secondary battery degradation determination device includes: a plurality of voltage sensor units 7 each of which individually detects the inter-terminal voltages of the plurality of batteries 2 in the corresponding battery group 3, individually calculates AC components from the detected signals, and transmits calculation results as measurement values by one wireless unit 10; current sensors 8 which detect currents of the respective battery groups 3; a measurement current application device 9 which applies a measurement current including an AC component, to the battery groups 3; and a controller 11 which receives the measurement values transmitted from each voltage sensor unit 7, calculates the internal resistance of each battery 2 by using the received measurement value, and determines degradation of the battery 2 on the basis of the internal resistance.

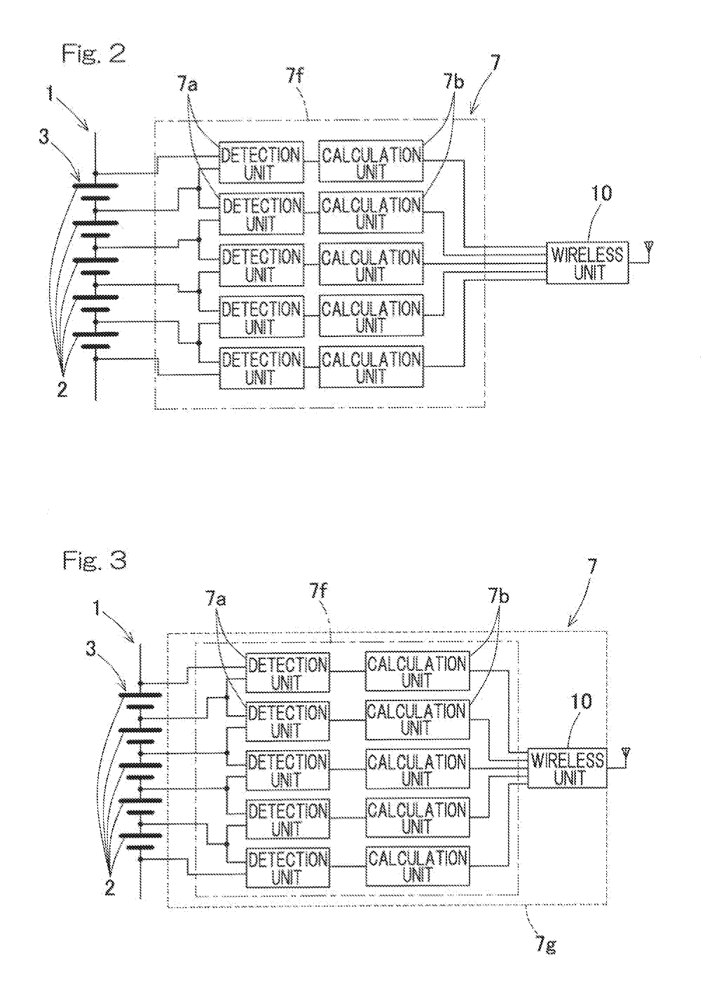

In this embodiment, as shown in FIG. 2, each voltage sensor unit 7 includes: a plurality of detection units 7a which individually detect the inter-terminal voltages of the batteries 2; and a plurality of calculation units 7b which individually calculate the AC components from signals detected by the respective detection units 7a. The voltage sensor unit 7 is, in other words, a sensor module. To describe a specific example, each detection unit 7a of the voltage sensor unit 7 is a voltage sensor that outputs an analog detection value of AC voltage as the above voltage detection value, and each calculation unit 7b converts the detection value that is an analog signal, to an effective value or an average value represented by a digital signal. In addition, the detection unit 7a has a function of detecting a DC voltage, and a detection value of the DC component is transmitted via the calculation unit 7b or directly by the wireless unit 10. The plurality of detection units 7a and the plurality of calculation units 7b form a detection calculation unit 7f. The appropriate number of the detection units 7a differs also depending on the voltage type of the battery 2, e.g., 2 V, 6 V, or 12 V. For example, it is preferable that the number of the detection units 7a is equal to or greater than 2 and is smaller than 10, or the number of the detection units 7a may be 2 to 8, or 4 to 6.

The voltage sensor unit 7 may be an integrated component in which all the components constituting the voltage sensor unit 7, such as the detection units 7a, the calculation units 7b, and the wireless unit 10, are assembled in one housing 7g as conceptually shown in FIG. 3. As a configuration in which all the components are assembled in one housing 7g, elements as these components may be mounted on the common circuit board, or the components may be formed as one integrated circuit chip. Such an integrated component is excellent in handling property and storage property.

In the sensor unit 7 in each example, the wireless unit 10 may have, in addition to the communication function, a control function for executing a given command, a delay function for delaying start of measurement by the detection unit 7a by a predetermined time with respect to a command, or the like. In this case, the wireless unit 10 may be configured such that, for example, the transmission order is preset with a transmission delay time, and the measurement value of each detection unit 7a is sequentially transmitted in the set order as the transmission delay time elapses. The wireless unit 10 has an antenna 10a (FIG. 7).

In addition, the voltage sensor unit 7 may have a temperature sensor (not shown) for measuring the temperature around the battery 2 or the temperature of the battery 2. The detected temperature from the temperature sensor is transmitted to the controller 11 by the wireless unit 10, together with the voltage measurement value that is the effective value or the average value calculated by the calculation unit 7b from the detected signal of each detection unit 7a.

In FIG. 1, the measurement current application device 9 is connected to positive and negative terminal ends of the battery groups 3 and applies a current including an AC component changing in a pulse shape or a sine wave shape, for example, a ripple current, to the power supply 1. The measurement current application device 9 is, for example, configured to generate a measurement current including an AC component on the basis of a commercial AC power supply and apply the measurement current to the battery groups 3 or charge them, or configured as a discharging circuit that discharges the power supply 1 to be subjected to degradation determination. In the configuration using the commercial AC power supply, the measurement current application device 9 is, more specifically, composed of: a transformer (not shown) that performs voltage conversion so that the voltage of the commercial AC power supply is adapted to the voltage of the emergency power supply 1; a capacitor (not shown) for separating only an AC component from the current converted by the transformer and applying the AC component to the battery groups 3; and a current limiting unit (not shown) such as a resistor that limits the current to be applied to the battery groups 3. A primary circuit of the transformer is provided with an opening/closing switch (not shown) that opens/closes or disconnects from/connects to the commercial power supply. Opening/closing of the opening/closing switch is controlled by the current application control unit 11e (see FIG. 7) in a later-described main controller 11A of the controller 11.

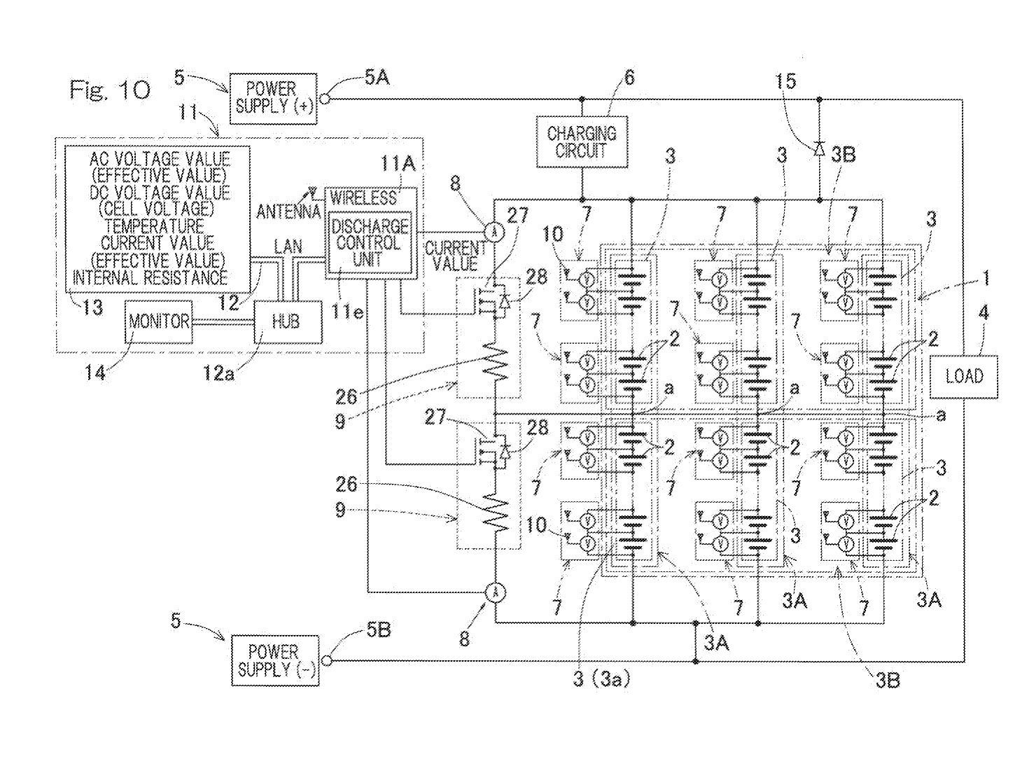

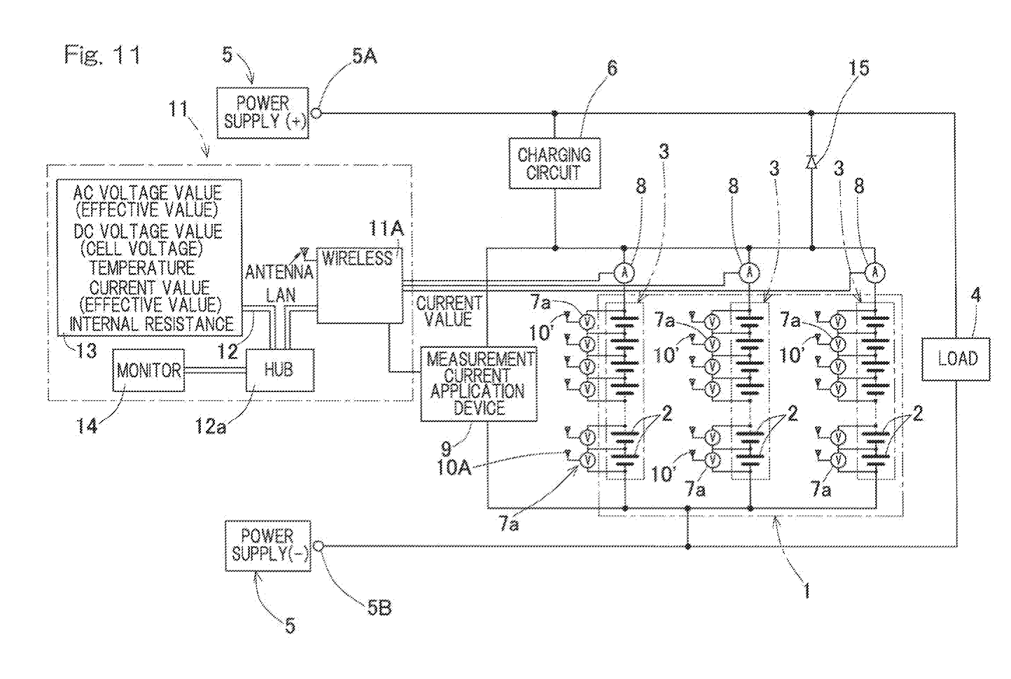

In the case of adopting the discharging circuit, for example, as shown in FIG. 10 in an embodiment described later, the measurement current application device 9 is configured by a discharging circuit composed of a series circuit of a current limiting resistor 26 and a switching element 27, and the discharging circuit is connected in parallel with the battery groups 3. A bypass diode 28 is provided to the switching element 27. The switching element 27 is driven to open/close by the current application control unit (discharge control unit) 11e in the main controller 11A (see FIG. 10) of the controller 11 such that the current flowing through the discharging circuit is a current having a pulse shape or a sine wave shape. In this case, the current application control unit 11e is configured to provide an instruction to drive the switching element 27 such that the current has a pulse shape or a sine wave shape. The other configurations in the embodiment in FIG. 10 will be described later.

In FIG. 1, in this embodiment, the controller 11 includes the main controller 11A, and a data server 13 and a monitor 14 connected to the main controller 11A via a communication network 12. The communication network 12 is composed of a LAN in this embodiment and has a hub 12a. The communication network 12 may be a wide area communication network. The data server 13 is able to communicate with a personal computer (not shown), etc., at a remote location via the communication network 12 or another communication network, and is able to perform data monitoring from any location.

As shown in FIG. 7, the main controller 11A has: a reception unit 11a that receives the detection values of the voltage sensor unit 7 transmitted from each wireless unit 10; a transfer unit 11b that transfers the measurement values received by the reception unit 11a, to the communication network 12; a command transmission unit 11c that wirelessly transmits a command for start of transmission, etc., to the wireless unit 10 of each voltage sensor unit 7; a standby unit 11d; and a current application control unit 11e. The current application control unit 11e controls the measurement current application device 9 (FIG. 1). Wireless transmission and reception by the command transmission unit 11c and the reception unit 11a are performed via an antenna 19.

The command transmission unit 11c of the main controller 11A may generate a command by itself. However, in this embodiment, in response to a measurement start command transmitted from the data server 13, the command transmission unit 11c transfers the measurement start command to the wireless unit 10 of each voltage sensor unit 7. The main controller 11A or the current sensor 8 is provided with a conversion unit (not shown) that converts the measurement value of the current sensor 8 to an effective value or an average value.

The data server 13 has an internal resistance calculation unit 13a and a determination unit 13b. The internal resistance calculation unit 13a calculates the internal resistance of the battery 2 according to a predetermined calculation formula by using the AC voltage value (the effective value or the average value) transmitted and received from the main controller 11A, the DC voltage value (cell voltage), the detection temperature, and the current value (the effective value or the average value). The detection temperature is used for temperature correction. Each current sensor 8 for obtaining the current value is connected via a wire to the main controller 11A, and the measurement value of the current is transferred by the transfer unit 11b in FIG. 7, together with the voltage measurement value.

A threshold is set in the determination unit 13b, and the determination unit 13b determines that degradation has occurred, when the calculated internal resistance is equal to or greater than the threshold. The threshold is set at a plurality of levels, for example, two or three levels, and degradation determination is performed at the plurality of levels. The determination unit 13b has a function to display the determination result on the monitor 14 via the communication network 12 or via a dedicated wire. In addition, the data server 13 has: a command transmission unit 13c that transmits the measurement start command to the main controller 11A; and a data storage unit 13d that stores therein data such as the voltage measurement value transmitted from the main controller 11A.

In the above configuration, the main controller 11A and the measurement current application device 9 may form an integral controller housed in a common case. In addition, although the controller 11 includes the main controller 11A and the data server 13 in this embodiment, the main controller 11A and the data server 13 may form a single controller 11 housed in a common case, or may be configured in one information processing device including one board or the like such that the main controller 11A and the data server 13 are not distinguished from each other on the board.

Operation of the degradation determination device having the above configuration will be described. FIG. 8 is a flowchart of an example of the operation. The data server 13 transmits the measurement start command to the command transmission unit 11c (step S1). The main controller 11A receives the measurement start command from the data server 13 (step S2) and transmits the measurement start command from the command transmission unit 11c to the wireless unit 10 of each voltage sensor unit 7 and each current sensor 8 (step S3). In parallel to processes after this transmission, the standby unit 11d performs determination of end of a standby time (step S20) and counts the standby time (step S22). When the set standby time ends (YES in step S20), the measurement current application device 9 applies a current (step S21). For the application of the current, discharging is started when the measurement current application device 9 is a discharging device, and charging is started when the measurement current application device 9 is a charging device.

All the voltage sensor units 7 receive the measurement start command transmitted in step S3 (step S4), and each voltage sensor unit 7 waits for end of the measurement delay time of each own detection unit 7a (step S5) and measures the DC voltage (inter-terminal voltage) of each battery 2 (step S6). Thereafter, the voltage sensor unit 7 waits for end of a standby time (step S7) and measures the AC voltage of the battery 2 (step S8). Regarding measurement of the AC voltage, the voltage sensor unit 7 converts a direct measurement value to an effective voltage or an average voltage and outputs the resultant conversion value as a measurement value.

The measured DC voltage and the measured AC voltage are, for example, after waiting for the corresponding transmission delay time, transmitted wirelessly by the wireless unit 10 (step S9), and the main controller 11A of the controller 11 wirelessly receives the measured DC voltage and the measured AC voltage (step S10). The main controller 11A transmits the received DC voltage and the received AC voltage together with the detection values of the current sensor 8 and the temperature sensor (not shown) to the data server 13 via the communication network 12 such as a LAN (step S11). The data server 13 receives sequentially transmitted data of the sensors such as the detection units 7a of each voltage sensor unit 7 and stores the data in the data storage unit 13d (step S12). The steps from the wireless transmission in step S9 until the data storage by the data server 13 are performed until reception and storage of the data of all the voltage sensor units 7 have been completed (No in step S12).

After the reception and the storage have been completed (YES in step S12), the current application of the measurement current application device 9 is turned off on the basis of transmission of a completion signal from the data server 13 to the main controller 11A and output of a current application control signal of the main controller 11A (step S16), and, in the data server 13, the internal resistance calculation unit 13a calculates the internal resistance of each battery 2 (step S13).

The determination unit 13b of the data server 13 compares the calculated internal resistance to a first threshold predetermined as appropriate (step S14). When the calculated internal resistance is less than the first threshold (YES in step S14), the determination unit 13b determines that the battery 2 is in a normal state (step S15). When the calculated internal resistance is not less than the first threshold (NO in step S14), the determination unit 13b further compares the calculated internal resistance to a second threshold (step S17). When the calculated internal resistance is less than the second threshold (YES in step S17), the determination unit 13b outputs a warning for drawing attention (step S18). When the calculated internal resistance is not less than the second threshold (NO in step S17), the determination unit 13b outputs an alert that is stronger than the warning (step S19). The warning and the alert are displayed on the monitor 14 (FIG. 1). When the calculated internal resistance is normal, the fact of normality may be displayed on the monitor 14, or does not have to be particularly displayed thereon. The alert and the warning may be displayed on the monitor 14, for example, by marks such as predetermined icons or by lighting predetermined portions, etc. In this manner, degradation determination is performed for all the batteries 2 of the emergency power supply 1 (in this example, degradation determination at two levels using two thresholds is performed).

According to the secondary battery degradation determination device, as described above, the voltage sensor unit 7 is provided for each battery 2, and data is passed and received as digital signals by means of wireless communication. Thus, even in the case with the emergency power supply 1 including dozens to hundreds of batteries 2, there is no need to care about reference potential (ground level) for each battery 2 from the electrical standpoint. Therefore, differential operation and an isolation transformer are not necessary. In addition, since the measurement value of each of such multiple detection units 7a is wirelessly transmitted, complicated wiring is not necessary. Accordingly, the configuration can be simple and inexpensive.

In this case, since the individual measurement values of the plurality of batteries 2 are transmitted by one wireless unit 10, the number of the wireless units 10 can be decreased, so that the entire configuration of the degradation determination device is simplified and thus the degradation determination device can be produced at low cost.

Degradation of the entire power supply 1 to be subjected to degradation determination is not determined, but degradation of each battery 2 is determined. In addition, for the determination, the measurement current including the AC component is applied, the internal resistance of each battery 2 is calculated by using the measurement value transmitted by each wireless unit 10, and degradation of the battery 2 is determined on the basis of the internal resistance. Thus, degradation determination can be accurately performed. The internal resistance of the battery 2 is closely related to the capacity of the battery 2, that is, the degree of degradation of the battery 2, and thus degradation of the battery 2 can be accurately determined when the internal resistance is known.

The measurement value measured by each detection unit 7a is converted to an effective value or an average value represented by a digital signal, and is transmitted. Thus, the amount of data transmitted can be significantly smaller than that in the case of transmitting a signal of a voltage waveform. The internal resistance of the battery 2 can be accurately calculated by using the effective value or the average value. Merely with measurement of a voltage, the calculation of the internal resistance of the battery 2 is possible, for example, by assuming a current as a constant value. However, the internal resistance can be more accurately calculated when a current actually flowing through the battery 2 is measured and both the voltage and the current are acquired. Since the currents flowing through the respective batteries 2 arranged in series are the same, it suffices that one current sensor 8 is provided for each battery group 3.

The controller 11 transmits the measurement start command to the wireless unit 10 of each voltage sensor unit 7, and measurement of each detection unit 7a is started by the command. Thus, the timing of start of measurement of the multiple detection units 7a can be synchronized with each other. In this case, the controller 11 simultaneously transmits the measurement start commands for the individual detection units 7a to each voltage sensor unit 7 by means of serial transmission or parallel transmission, and each detection unit 7a simultaneously performs measurement after the measurement start delay time elapses. After the measurement, the controller 11 sequentially transmits a data transmission request command to each voltage sensor unit 7, and the voltage sensor unit 7 that has received the command transmits data obtained through calculation by the calculation unit 7b for the detection unit 7a corresponding to the command. By repeating the above operations, data communication may be performed. In this embodiment, after a certain time from the transmission of the data transmission request command, the controller 11 may make a retransmission request to the voltage sensor unit 7 from which the controller 11 fails to receive data.

As another example, in the case where measurement is performed after elapse of a measurement start delay time predetermined for each detection unit 7a of each voltage sensor unit 7, even when the measurement start command is simultaneously transmitted to each wireless unit 10, measurement by each detection unit 7a of the multiple voltage sensor units 7 can be sequentially performed without interfering with wireless transmission and reception, and transmission can be performed. For example, a transmission start command is a global command, and the voltage sensor units 7 simultaneously acquire the transmission start command.

After a certain time from the transmission of the measurement start command, the controller 11 makes a retransmission request to the voltage sensor unit 7 from which the controller 11 fails to receive data. Due to any temporary transmission problem or the like, the measurement start command cannot be received by the wireless units 10 of some voltage sensor units 7 in some cases. Even in such a case, as a result of making the retransmission request, a voltage can be measured and transmitted, so that the voltage measurement values of all the batteries 2 of the power supply can be acquired. Whether the measurement start command has been received may be determined by determining whether the measurement value of the voltage has been received by the controller 11.

The controller 11 may individually transmit a data request command to the wireless unit 10 of each voltage sensor unit 7, rather than simultaneously transmitting the measurement start command as described above, and may sequentially receive data therefrom. In the case of this configuration, the delay function is unnecessary in the voltage sensor unit 7, and the configuration of the voltage sensor unit 7 is simplified. Since the controller 11 outputs alerts at a plurality of levels in accordance with the magnitude of the calculated internal resistance, the urgency of the need for battery replacement is recognized, and maintenance can be smoothly and quickly planned and prepared without wasted battery replacement.

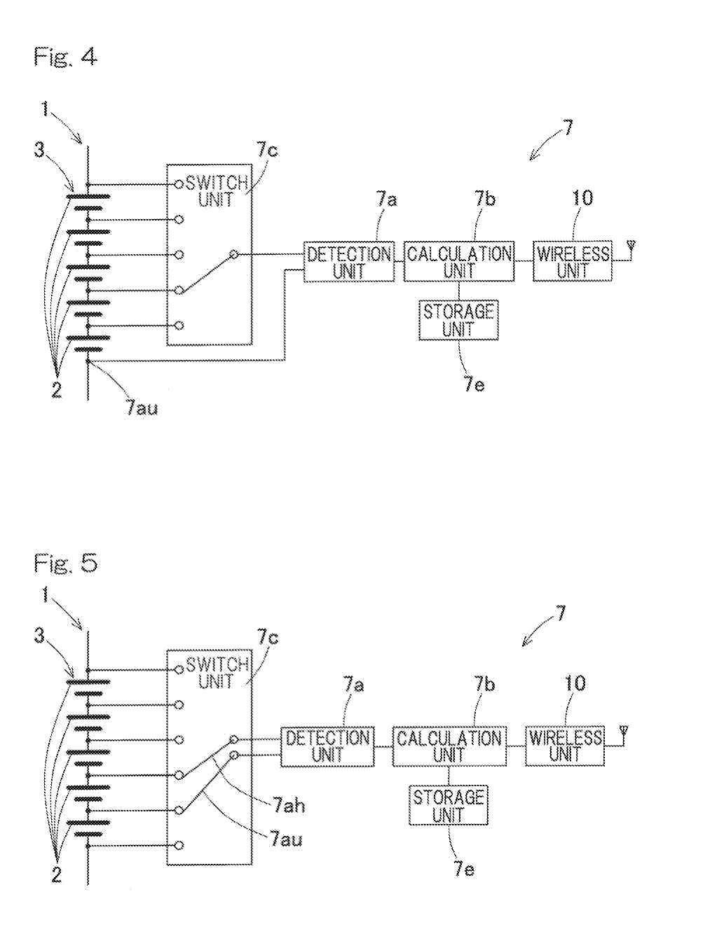

In the above embodiment, the voltage sensor unit 7 is configured, to be valid, such that the detection unit 7a which is a voltage sensor and the calculation unit 7b are provided for each battery 2 that is subjected to degradation detection. However, as shown in a modification in FIG. 4 or FIG. 5, the voltage sensor unit 7 may be composed of: one detection unit 7a that individually detects the inter-terminal voltage; a switch unit 7c that performs switching among the plurality of batteries 2 to be connected to the detection unit 7a; and one calculation unit 7b that individually calculates the AC component from a signal detected by the detection unit 7a. The AC component which is a calculation result of the calculation unit 7b and the DC component obtained by the detection unit 7a are temporarily stored in a storage unit 7e, and the stored calculation result is transmitted by the wireless unit 10. It is noted that the storage unit 7e may not necessarily be provided, and in this case, every time the calculation unit 7b performs calculation, the calculation result is transmitted by the wireless unit 10.

In the case of the configurations shown in FIG. 4 and FIG. 5, only the switch unit 7c is connected to the input side of the detection unit 7a, and therefore the wiring is simplified. In the example shown in FIG. 4, the switch unit 7c uses in common a terminal 7au having the lowest potential among the plurality of batteries 2 connected in series that are subjected to detection by the corresponding one voltage sensor unit 7. In the case of this configuration, the configuration of the switch unit 7c is simplified. In the example shown in FIG. 5, the switch unit 7c is configured to sequentially switch, for each battery 2, both terminals 7au, 7ah on the low potential side and the high potential side that are to be connected to the detection unit 7a. In the case of this configuration, although the switch unit 7c is needed, the required number of the detection units 7a and the required number of the calculation units 7b are both only one. Therefore, the number of circuit elements for the detection unit 7a, the calculation unit 7b, or the switch unit 7c is decreased.

FIG. 6 shows a modification of the voltage sensor unit 7. In this example, the voltage sensor unit 7 includes: a plurality of detection units 7a which individually detect the inter-terminal voltages of the batteries 2; a data selecting unit 7d which switchably selects the signal detected by each detection unit 7a and outputs the selected signal; and one calculation unit 7b which individually calculates the AC component from the signal selected by the data selecting unit 7d. In addition, the voltage sensor unit 7 includes a storage unit 7e which stores a result of calculation by the calculation unit 7b. The voltage measurement value of each battery 2 which has been detected by each detection unit 7a, selected by the data selecting unit 7d, and then converted to an effective value or the like by the calculation unit 7b, is once stored into the storage unit 7e, and then sequentially outputted by the wireless unit 10. Each detection unit 7a is formed from a differential operation circuit, and the plurality of detection units 7a formed from the differential operation circuits constitute a differential operation unit 7aA formed from a sensor array, a sensor module, or the like.

In the case of providing the data selecting unit 7d as in the above example, the required number of the calculation units 7b is only one. Therefore, the number of circuit elements composing the detection unit 7a, the calculation unit 7b, or the data selecting unit 7d is decreased.

FIG. 9 shows a second embodiment of the present invention. In this embodiment, one current sensor 8 is provided for the power supply 1 subjected to degradation detection, instead of the configuration in which the current sensor 8 is provided for each battery group 3 in the first embodiment shown in FIG. 1. Regarding measurement of currents of the battery groups 3, as shown in the example in FIG. 9, even in the case where one current sensor 8 is provided for the entire power supply 1 so as to detect a current flowing through the battery groups 3, in practice, there might be almost no difference in terms of calculation for the internal resistance of each battery 2, as compared to the case where the current sensor 8 is provided for each battery group 3. Therefore, in the case of providing one current sensor 8 for the entire power supply 1, it is possible to achieve configuration simplification and cost reduction by decrease in the number of the current sensors 8 while keeping accuracy in degradation detection.

A specific description will be given. For example, as shown in FIG. 10, in the case where the measurement current application device 9 is composed of a discharging circuit and a current limiting resistor 26 is used, the current limiting resistor 26 has sufficiently higher resistance than the internal resistance of the battery 2, and thus change of the battery internal resistance due to degradation has almost no effect on the current value. Therefore, even when the plurality of the battery groups 3 are connected in parallel, a value obtained by dividing a current value, measured at the position of the discharging circuit (the measurement current application device 9), by the number of the battery groups 3 connected in parallel can be used as a measurement current for each battery 2.

For example, in the case where the current limiting resistor 26 has a resistance of 20 to 30 Ω, since the battery internal resistance is about several milliohms to 10 m Ω, if the battery internal resistance is assumed as 10 m Ω and 150 batteries are connected in series, the total internal resistance is 1.5 Ω. When three battery rows each including 150 batteries are connected in parallel, the total internal resistance is 0.5, which is smaller than that of the current limiting resistor 26. Here, even when 10% of the internal resistances is doubled due to degradation, the total internal resistance is 0.55 Ω, and the total impedance is merely changed from 20.5 Ω to 20.55 Ω, which has a small effect on the measurement current. Therefore, the current sensor 8 may be shared. The other matters in the embodiment shown in FIG. 9 are the same as those in the embodiment shown in FIG. 1.

FIG. 10 shows a third embodiment of the present invention. The matters other than matters specifically described in this embodiment are the same as those in the first embodiment described with reference to FIG. 1, etc. In FIG. 10, one wireless unit 10 (and an antenna connected thereto) is provided for each battery 2. However, the wireless unit 10 may be provided for each voltage sensor unit 7 as in the first and second embodiments.

In FIG. 10, in the power supply 1, a plurality of battery groups 3 are connected in series to form a series-connection assembly 3A, and a plurality of the series-connection assemblies 3A including the battery groups 3 are connected in parallel. Among the series-connection assemblies 3A of the battery groups 3, parts “a” between the individual battery groups 3 corresponding to each other are connected to each other, and the battery groups 3 are connected in parallel to form a parallel-connection assembly 3B. The measurement current application device 9 and the current sensor 8 are provided for each parallel-connection assembly 3B including the battery groups 3. In this example, the measurement current application device 9 is configured as the discharging circuit described above.

In other words, when each series-connection assembly 3A in the power supply 1 is regarded or assumed as one battery group 3, this one battery group 3 is divided into a plurality of (two) battery group division bodies 3a aligned in the series direction, and the battery group division bodies 3a are connected in parallel with other battery group division bodies 3a forming other battery groups 3. The measurement current application device (discharging circuit) 9 is provided in parallel with each connection assembly including these battery group division bodies 3a connected in parallel (that is, each parallel-connection assembly 3B). The number of battery group division bodies 3a obtained by division is not limited, but a plurality of the batteries 2 are connected in series in each battery group division body 3a.

In the case where the power supply 1 is an emergency power supply in a data center or the like, the voltages of the series-connection assemblies of the batteries 2 in the entire power supply 1 are each a high voltage exceeding, for example, 300 V. Thus, when the measurement current application device (discharging circuit) 9 is provided for the entire power supply 1, the switching element 27 that is a power element for applying a measurement current needs to be element having high voltage resistance. However, since each series-connection assembly of the batteries 2 is configured to be divided into two sections in the series direction as in this embodiment, element having low voltage resistance can be used as the switching element 27, which is a power element for measurement current application in the measurement current application device (discharging circuit) 9.

Although the present invention has been fully described in connection with the preferred embodiments thereof with reference to the accompanying drawings, numerous additions, modifications and omissions can be made without departing from the gist of the present invention. Accordingly, such additions, modifications and omissions are to be construed as included in the scope of the present invention.

### REFERENCE NUMERALS

1 . . . power supply
2 . . . battery
3 . . . battery group
4 . . . load
15 . . . main power supply
5A, 5B . . . terminal
6 . . . charging circuit
7 . . . voltage sensor unit
7a . . . detection unit
7b . . . calculation unit
7c . . . switch unit
7d . . . data selecting unit
7e . . . storage unit
7g . . . housing
8 . . . current sensor
9 . . . measurement current application device
10 . . . wireless unit
11 . . . controller
11A . . . main controller
11e . . . current application control unit
12 . . . communication network
13 . . . data server
13a . . . internal resistance calculation unit
13b . . . determination unit
14 . . . monitor
15 . . . diode

What is claimed is:

1. A secondary battery degradation determination device that determines degradation of a battery in a power supply in which a plurality of battery groups each including a plurality of batteries that are secondary batteries and are connected in series are connected in parallel, the secondary battery degradation determination device comprising:
a plurality of voltage sensor units each configured to individually detect inter-terminal voltages of the plurality of batteries in the corresponding battery group, individually calculate AC components from detected signals thereof, and transmit calculation results as measurement values by one wireless unit;
a current sensor configured to detect a current of each battery group;
a measurement current application device configured to apply a measurement current including an AC component to the battery groups; and
a controller configured to receive the measurement values transmitted from each voltage sensor unit, calculate an internal resistance of each battery by using the received measurement values, and determine degradation of each battery on the basis of the internal resistance.

2. The secondary battery degradation determination device as claimed in claim 1, wherein
each voltage sensor unit includes: a plurality of detection units configured to individually detect the inter-terminal voltages; and a plurality of calculation units configured to individually calculate the AC components from signals detected by the respective detection units.

3. The secondary battery degradation determination device as claimed in claim 1, wherein
each voltage sensor unit includes: one detection unit configured to individually detect the inter-terminal voltages; a switch unit configured to perform switching among the plurality of batteries to be connected to the detection unit; and one calculation unit configured to individually calculate the AC component from each signal detected by the detection unit.

4. The secondary battery degradation determination device as claimed in claim 1, wherein
each voltage sensor unit includes: a plurality of detection units configured to individually detect the inter-terminal voltages; a data selecting unit configured to switchably select a signal detected by each detection unit and output the selected signal; and one calculation unit configured to individually calculate the AC component from the signal selected by the data selecting unit.

5. The secondary battery degradation determination device as claimed in claim 1, wherein
an entirety of each voltage sensor unit is an integrated component in which all constituent elements thereof are assembled in one housing.

6. The secondary battery degradation determination device as claimed in claim 3, wherein
the switch unit uses in common a terminal having the lowest potential among the plurality of batteries connected in series that are subjected to detection by the corresponding one voltage sensor unit.

7. The secondary battery degradation determination device as claimed in claim 3, wherein
the switch unit sequentially switches, for each battery, both terminals on a low potential side and a high potential side that are to be connected to the detection unit.
